(19) United States
(12) Patent Application Publication
(10) Pub. No.: US 2024/0271319 A1
(43) Pub. Date: Aug. 15, 2024

(54) REACTION CHAMBER WITH COVERING SYSTEM AND EPITAXIAL REACTOR

(71) Applicant: LPE S.P.A., Baranzate (MI) (IT)

(72) Inventors: Srinivas Yarlagadda, Baranzate (MI) (IT); Silvio Preti, Baranzate (MI) (IT); Francesco Corea, Baranzate (MI) (IT); Stefano Polli, Baranzate (MI) (IT)

(21) Appl. No.: 18/567,983

(22) PCT Filed: Jun. 7, 2022
(86) PCT No.: PCT/IB2022/055281

§ 371 Date: Dec. 7, 2023

(30) Foreign Application Priority Data
Jun. 9, 2021 (IT) 102021000014984

(51) Int. Cl. C30B 25/08; C23C 16/44; C23C 16/458; C23C 16/46; C30B 25/10; C30B 25/12

(52) U.S. Cl. CPC C30B 25/08; C23C 16/4401; C23C 16/4584; C23C 16/46; C30B 25/10; C30B 25/12

(57) ABSTRACT

The reaction chamber (100) comprises a covering system (90) that is located within its cavity (101) and comprises at least one lower covering element (120) resting on a lower wall of the cavity, and an upper covering element (130) resting on the lower covering element (120); the lower covering element (120) and the upper covering element (130) define an insulated inner space to accommodate at least one substrate, and make four walls surrounding this inner space and are spaced apart from the cavity walls; the walls of the chamber (100) are typically made of quartz and the covering system (90) is typically made of quartz.

### FIELD OF THE INVENTION

The present invention relates to a reaction chamber for an epitaxial reactor with a “covering system” and related reactor. The (non-contact) “covering system” of the chamber walls serves to define a space that is inside the cavity of the reaction chamber and that is insulated.

### STATE OF THE ART

The Applicant is the owner of an International Patent Application published under number WO2010119430 related to a reaction chamber for an epitaxial reactor with a covering system. The reaction chamber is provided with a box-shaped cavity surrounded by four walls, wherein reaction and deposition processes of semiconductor material on substrates occur; the substrates are placed on a rotating susceptor disc. The reaction chamber comprises a covering system located within the cavity that defines an inner space within the cavity and an outer space also within the cavity. The covering system consists of three elements, a first vertical counter-wall and an upper and second vertical counter-wall, which form an inverted “U”-shaped slab that rests on the lower wall of the reaction chamber.

The term “counter-wall” means in this Patent Application a wall located at a certain distance from the reference wall and not in contact with it, there being an empty cavity in between—the reactor is made in such a way that in general there is gas in the cavity and in particular during the reaction and deposition processes there is gas in the cavity, in particular process gas or inert gas, depending on the location and on the embodiment.

### SUMMARY

The solution according to WO2010119430, which is herein mentioned in its entirety, is a simple and effective solution, but creates an inner “partial covering” of the reaction chamber as no lower counter-wall is provided.

The general object of the present invention is to improve the prior art.

In particular, the objects of improving the “chemical” insulation of the inner space and/or the “thermal” insulation of the inner space and/or the soiling of the inner surfaces of the reaction chamber walls (in the sense of reducing it) and/or the possibility of local temperature control in the lower area of the reaction chamber were identified.

It should be noted that this inner space of the reaction chamber cavity is adapted to contain a susceptor disc and, during epitaxial growth processes, also substrates on which epitaxial deposition of semiconductor material occurs.

As known, there is an interest in high thickness uniformity and high quality of the semiconductor material layers deposited on the substrates.

This general object as well as at least these objects are reached thanks to what set forth in the appended claims that form an integral part of the present description.

### LIST OF FIGURES

The present invention shall become more readily apparent from the detailed description that follows to be considered together with the accompanying drawings in which:

FIG. 1 shows a first schematic and simplified (not in scale) cross-section (in the longitudinal direction) of a first embodiment of a reaction chamber according to the present invention—the figure is subdivided into three views: View A shows only a chamber, View B shows only the components of the covering system, View C shows the chamber with the covering system housed therein,

FIG. 2 shows a second schematic and simplified cross-section (not in scale) of the embodiment of FIG. 1,

FIG. 3 shows a first schematic and simplified horizontal section (not in scale) at a first elevation of the embodiment of FIG. 1,

FIG. 4 shows a second schematic and simplified horizontal section (not in scale) at a second elevation of the embodiment of FIG. 1,

FIG. 5 shows a third schematic and simplified horizontal section (not in scale) at a third elevation of the embodiment of FIG. 1,

FIG. 6 shows a fourth schematic and simplified horizontal section (not in scale) of the embodiment of FIG. 1,

FIG. 7 shows a fifth schematic and simplified horizontal section (not in scale) at a fifth elevation of the embodiment of FIG. 1,

FIG. 8 shows a sixth schematic and simplified horizontal section (not in scale) of the embodiment of FIG. 1,

FIG. 9 shows an exploded perspective view of a second embodiment of a reaction chamber according to the present invention (slightly different from the first), and

FIG. 10 shows a schematic, partially sectioned side view of the embodiment of FIG. 9 combined with a tank.

As is easily understood, there are various ways of practically implementing the present invention, which is defined in its main advantageous aspects in the appended claims and is neither limited by the detailed description that follows nor by the appended drawings, which refer to two slightly different embodiments.

It is specified that the technical characteristics set out hereinafter in relation to specific embodiments are not to be regarded as strictly interlinked and therefore mutually binding.

### DETAILED DESCRIPTION

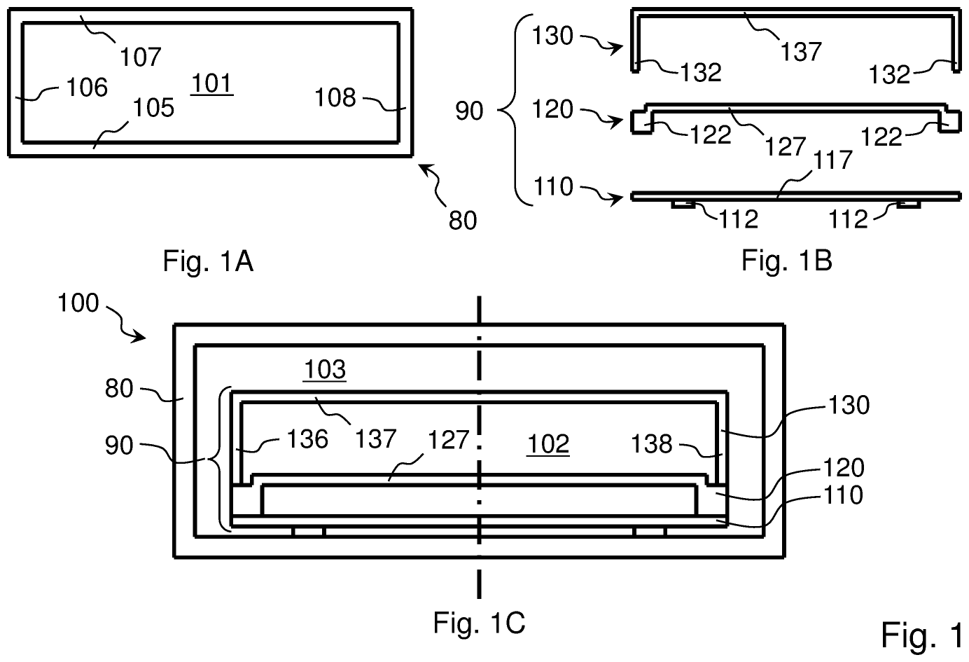

Referring to figures from FIG. 1 to FIG. 8, a reaction chamber 100 for an epitaxial reactor according to the present invention comprises a chamber 80 and a covering system 90 combined with each other, as shown for example in FIG. 1C; FIG. 1A shows only the chamber 80 and FIG. 1B shows only the covering system 90. The chamber 80 is provided with a box-shaped cavity 101.

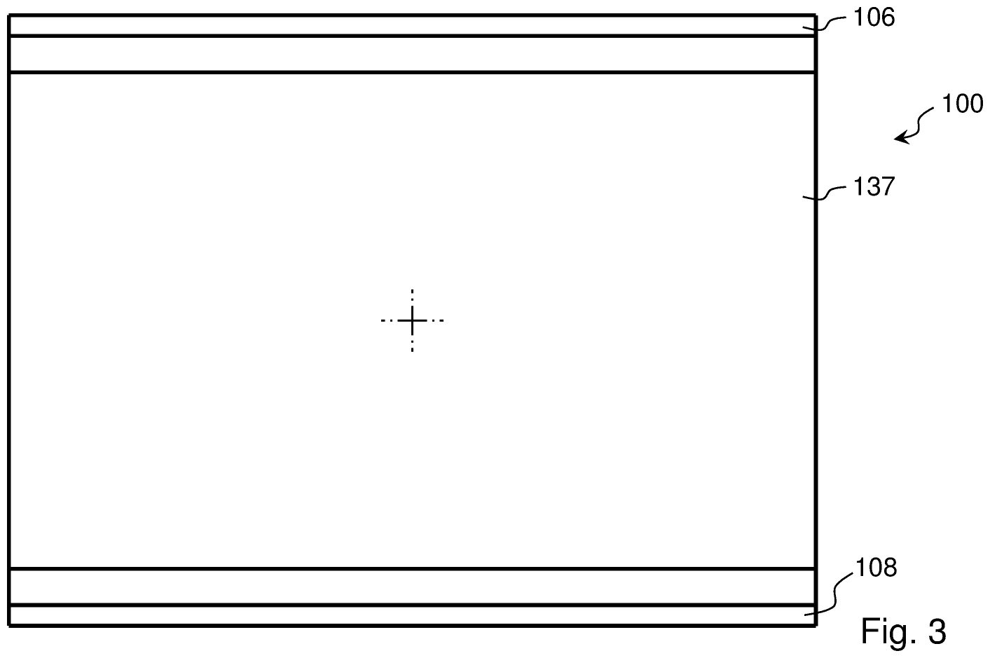

The dimensions for the figures from FIG. 3 to FIG. 8 will be clarified later.

The cavity 101 is surrounded by at least four walls of the chamber 80: a lower wall 105, a first side wall 106 (on the left), an upper wall 107, and a second side wall 108 (on the right); according to this embodiment, the chamber 80 has neither a front nor a back wall because at the front the reaction gases enter and at the back the exhaust gases exit. These are in particular essentially four flat slabs, for example, made of transparent quartz, joined together at their longitudinal edges; the structure of the chamber may be more complex, as will be seen hereinafter, and comprises, for example, flanges at the front and/or back and/or reinforcing ribs and/or small outer partition walls.

In the cavity 101, reaction and deposition processes of semiconductor material on substrates occur; more precisely, and as will be clarified hereinafter, according to the present invention, such processes occur only in an “inner space” of the cavity.

The reaction chamber 100 comprises a “covering system” 90 located entirely within the cavity 101; the “covering system” of the chamber walls, which is not in contact with them (except for lower support elements which are few and small and low), serves to define the “inner space”.

The covering system 90 comprises at least:
a lower covering element 120 resting directly or indirectly on the lower wall 105 of the cavity 101, and
an upper covering element 130 resting directly or indirectly on the lower covering element 120.

The lower covering element 120 and the upper covering element 130 define an “inner space” 102 comprised in the cavity 101 and an “outer space” 103 comprised in the cavity 101, and create at least four walls 127, 136, 137, 138 surrounding the inner space 102.

These four walls 127, 136, 137, 138 of the inner space 102 are spaced from the corresponding four walls 105, 106, 107, 108 of the cavity 101 by means of an empty space wherein there may be gas, in particular process gas or inert gas, depending on the position and embodiment; they may therefore be considered as counter-walls; the consideration regarding the front and back made above for the cavity walls also applies to the walls of the inner space. In addition to the empty space, there may be possible support elements of the covering system (see for example elements 112 and 122 in FIG. 1) that contribute to achieve distancing.

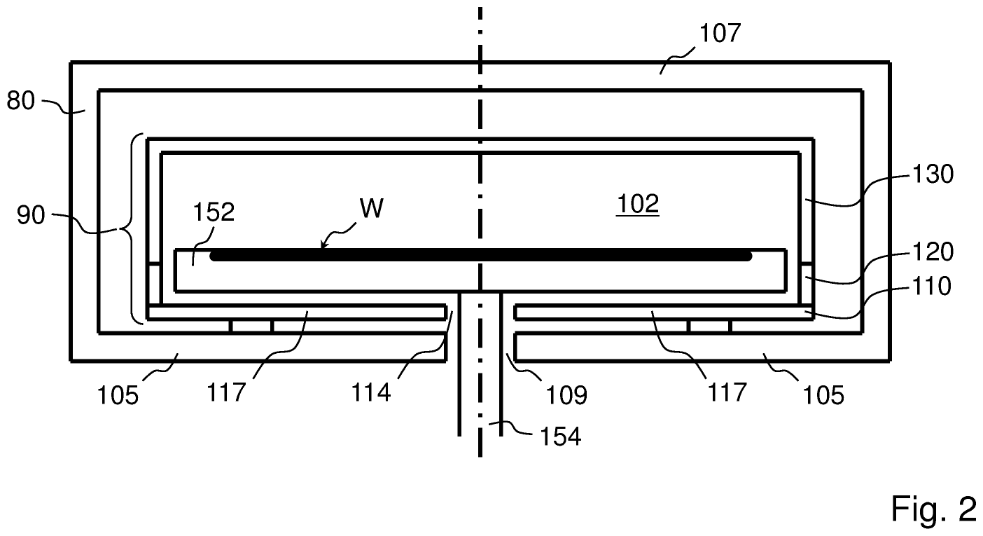

The inner space 102 is adapted to accommodate at least one or more substrates subject to deposition of semiconductor material; the substrate or substrates rest (directly or indirectly) on a susceptor 150, in particular on a susceptor disk 152 (see, for example, FIG. 2); typically, the susceptor is adapted to remain inside the reaction chamber at all times, i.e. both during the reaction and deposition processes and before and after such processes.

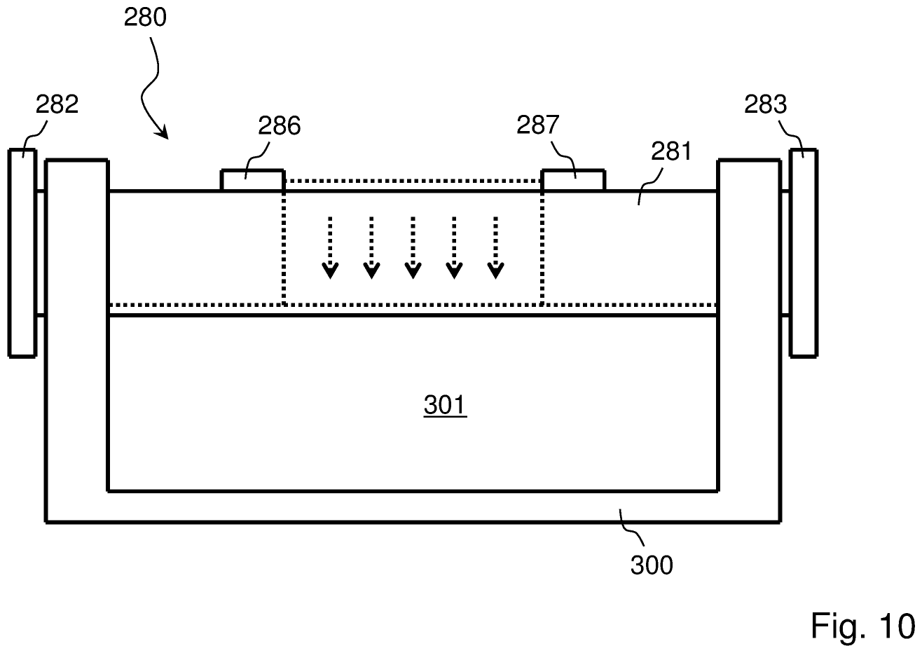

The covering system according to the present invention may be configured in such a way as to house at least the disc of the substrate supporting susceptor. Such disc is made of graphite and is adapted to be heated by induction. In the figures, the disc heating system is not shown; this advantageously consists of at least one flat inductor located proximate to the disc outside the chamber (e.g. below the lower wall); with reference to FIG. 10, for example, the inductor could be in the cavity 301 adequately electrically insulated from water. Advantageously, the heating system of the reaction chamber according to the present invention is of the induction type, but the use of lamps (e.g. above the upper wall) is not excluded.

The inner space 102 is isolated from the outer space 103 by means of a constant and uniform contact between the element 120 and element 130.

It can be understood from the set of FIG. 1C and FIG. 2 that the upper surface of the susceptor disk 152 is aligned with the upper surface of the wall 127 made by the element 120; in particular, these surfaces are also aligned with the upper surfaces of any substrates W supported by the susceptor disk 152 within specific recesses. Advantageously, the cavity walls are made entirely of quartz and the covering system is made entirely of quartz; quartz may be of different types depending on the location. Thus, the walls of the cavity and the covering system do not actively contribute to the heating of the cavity, in particular of its “inner space” and the substrate(s); in other words, the reaction chamber according to the present invention is not of the hot-wall type. In the case of the embodiments of the figures (in particular that of FIG. 2 to FIG. 10), the only element that actively contributes to the heating of the cavity, in particular of its “inner space” and substrate(s), is the susceptor, in particular its rotating disc.

Typically and preferably, the covering system 90 further comprises a base covering element 110 that rests directly on the lower wall 105 of the cavity 101 and serves as a further (indirect) closing element of the inner space 102; in this case, the lower covering element 120 rests directly or indirectly on the base covering element 110. The covering element 130 may be schematised as an inverted “U”-shaped slab (see for example FIG. 1B). The covering element 120 may be schematised as an inverted “U”-shaped slab (see for example FIG. 1B). The covering element 110 may be schematised as a flat slab (see for example FIG. 1B), except for the “feet” which will be discussed hereinafter.

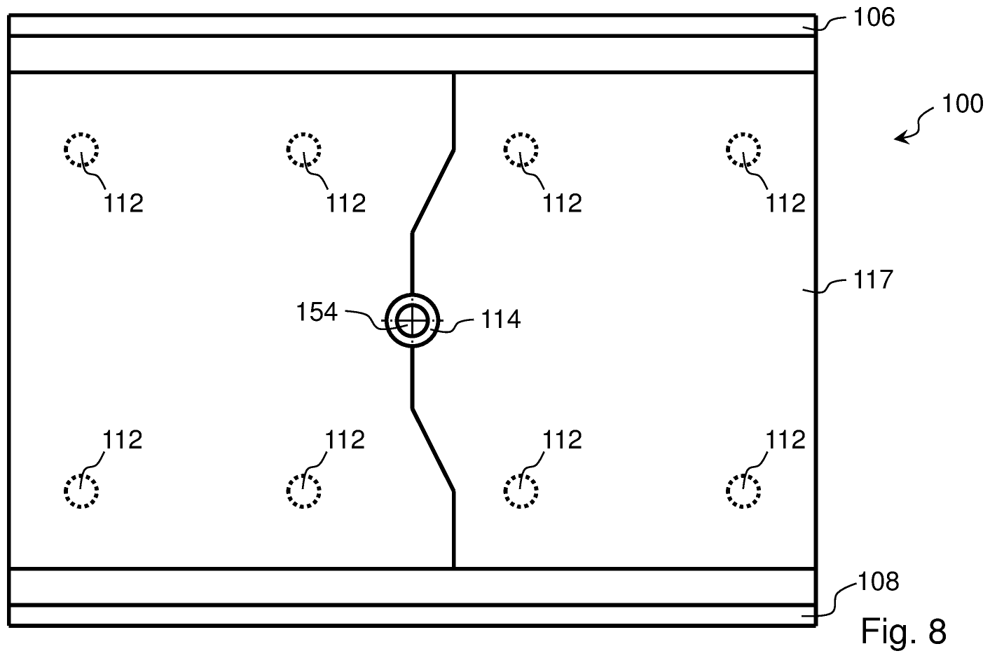

Typically and preferably, the base covering element 110 rests directly on the lower wall 105 of the cavity 101 only through support elements 112. In FIG. 8, eight support elements, known as “feet”, are shown as an example, four for a first part and four for a second part, but their number may be different, i.e. lower or higher (there are, however, a few, for instance ranging from a minimum of 3 to a maximum of 30). The support elements are typically small; for example, each may have a support area of between 3 mm² and 300 mm². The support elements are typically low; for example, they may be between 0.5 mm and 5.0 mm high.

The base covering element 110 is essentially in the form of a flat rectangular slab 117.

The base covering element 110 is made of transparent quartz.

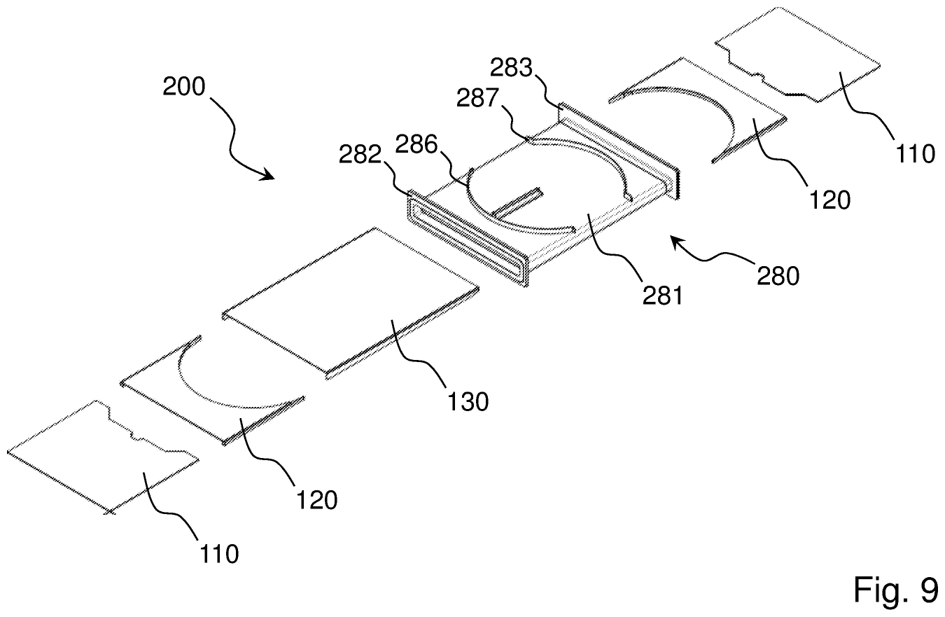

The base covering element 110 consists of two pieces (substantially equal to each other) that mechanically couple together; in particular, a first one of the two pieces is located upstream and a second one of the two pieces is located downstream considering a reaction gas flow direction. This is visible in particular in FIG. 9.

The base covering element 110 has a (small) central hole 114 adapted for the passage of a rotation shaft 154 of a substrate-supporting susceptor 150; the diameter of the hole and the diameter of the shaft differ only slightly (e.g. 2-20 mm). In particular, the two pieces of the slab each define half of the hole by their mechanical coupling edge.

The upper covering element 130 is in the form of a flat rectangular slab 137 preferably with two shoulders 132 at two opposite longitudinal edges of the flat slab. It may be said that the element 130 is in the form of an inverted “U”-shaped slab. The two shoulders 132 create two side walls 136 and 138 of the inner space 102; the slab 137 creates an upper wall of the inner space 102.

The upper covering element 130 is made of transparent quartz.

The upper covering element 130 consists of a single piece.

The lower covering element 120 is in the form of a rectangular flat slab 127 preferably with shoulders, e.g. longitudinal shoulders 122 and/or transverse shoulders 123, in correspondence of at least some edges of the flat slab; in particular, there are shoulders 122 at two opposite longitudinal edges of the flat slab (see, for example, FIG. 1B and FIG. 1C). It may also be said that the element 120 has the shape of an inverted “U”-shaped slab. The slab 127 creates a lower wall of the inner space 102.

The lower covering element 120 is made of opaque quartz.

The lower covering element 120 consists of two pieces (substantially equal to each other) that mechanically couple together; in particular, a first one of the two pieces is located upstream and a second one of the two pieces is located downstream considering a reaction gas flow direction. This is visible in particular in FIG. 9.

As shown in FIG. 1C, the shoulders 132 of the element 130 rest directly on the shoulders 122 of the element 120, in particular on an outer area, and the slab 127 rests on an inner area of the shoulders 122.

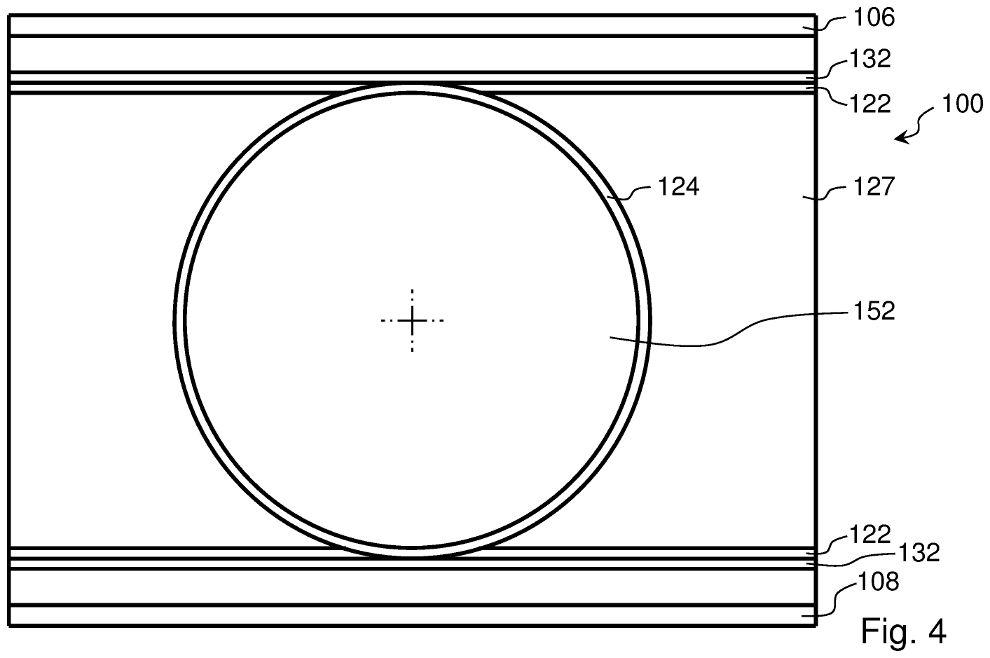

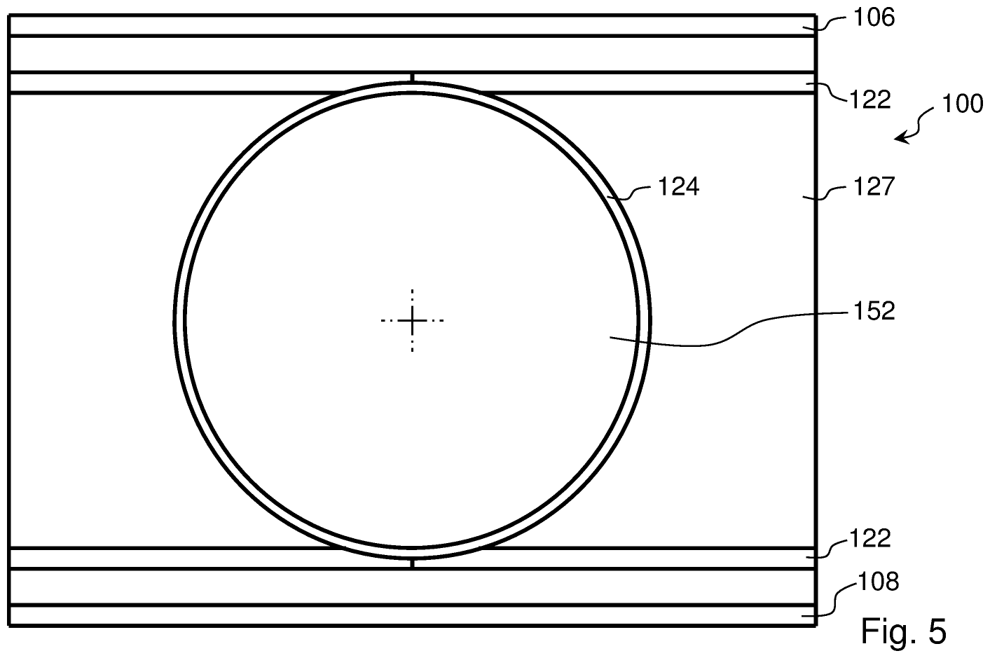

The lower covering element 120, in particular the flat slab 127, has a (large) central hole 124 adapted to receive a disc 152 of a substrate-supporting susceptor 150; the diameter of the hole and the diameter of the disc differ only slightly (e.g. 2-20 mm) and the relevant gap is crossed by a small flow of reaction gas which exits the space 102 and enters the space between the wall 127 and the wall 117. This is visible in particular in FIG. 4 and FIG. 5.

The bottom covering element 120 has a width slightly (e.g. 2-20 mm) greater than the diameter of the central hole 124.

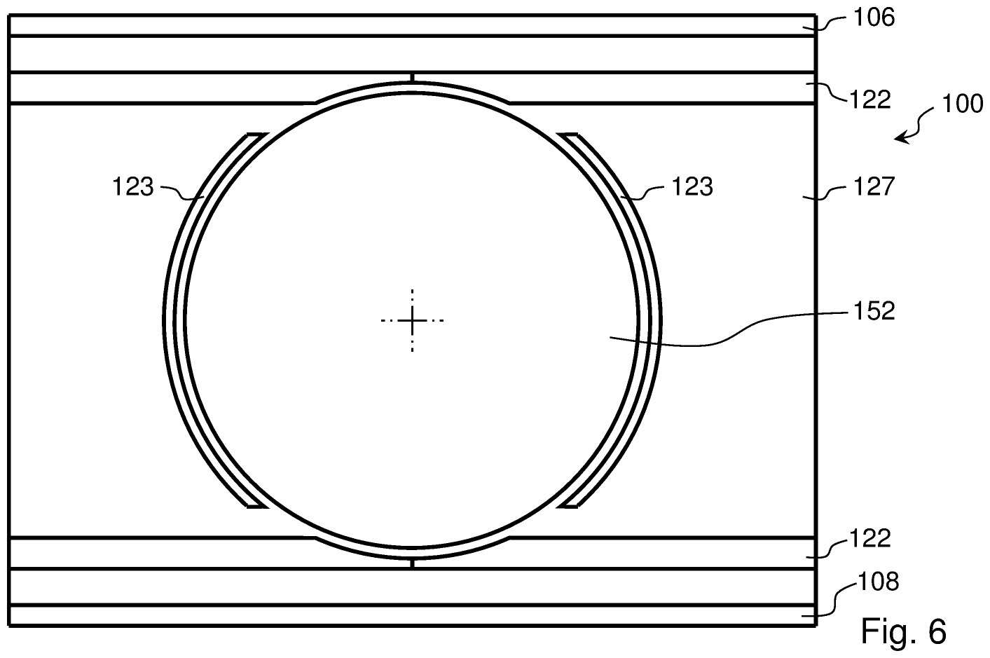

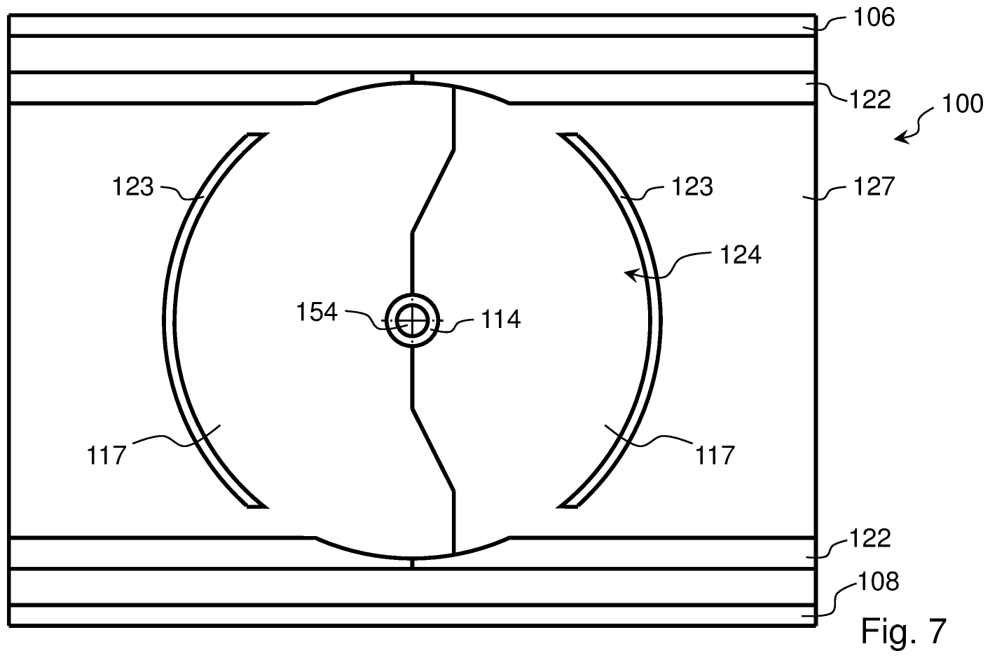

The lower covering element 120 has longitudinal shoulders 122 at two opposite longitudinal edges of the flat slab and/or transverse shoulders 123 at the central hole 124 (see for example FIG. 6 and FIG. 7). It should be noted that the shoulders 123 are not joined to the shoulders 122 (there are spacings) so that there are no totally dead spaces for the circulation of gas, this eases manufacturing the element 120 in particular welding its components.

In the lower wall 105 of the chamber 80, there is a (small) hole 109 adapted for the passage of a rotation shaft 154 of a substrate supporting susceptor 150; the diameter of the hole and the diameter of the shaft differ only slightly (e.g. 2-20 mm). It is advantageous to inject a gaseous flow of, for example, hydrogen from the rotation shaft 154 of the susceptor 150 into the reaction chamber to put the area at the holes 109 and 114 under slight overpressure and to prevent reaction gases from escaping from the cavity 101, in particular from the space 102 and the space 103 and the space between the wall 127 and the wall 117.

From FIG. 5 and FIG. 6 and FIG. 7, it may be seen that according to this embodiment, the shoulders 122 of the element 120 are slightly thinned at their intermediate area, in particular at the transverse plane passing through the centre of the hole 124. In this example, the point of maximum thinning is where the upstream and downstream parts come into contact. The difference in the section of the shoulders 122 may also be seen by comparing FIG. 1C and FIG. 2.

It is clear from the figures in this first embodiment that the space 102 is very well insulated except for the small (e.g. 2-20 mm) gap between the shaft 154 and the perimeter of the hole 114 in the wall 117.

According to the first embodiment, the elements of the reaction chamber may have, by way of exemplary and non-limiting purposes, the following dimensions:
length of the elements 106 and 108 in FIG. 1A (i.e. height of the room 80): 75 mm,
length of the elements 105 and 107 in FIG. 1A (i.e. width of the chamber 80): 800 mm,
thickness of elements 105-108 in FIG. 1A: 8 mm,
length of the element 132 in FIG. 1B: 50 mm,
length of the element 137 in FIG. 1B: 780 mm,
thickness of elements 132 and 137 in FIG. 1B: 3 mm,
length of the element 122 in FIG. 1B: 20 mm,
length of the element 127 in FIG. 1B: 780 mm,
thickness of the element 122 in FIG. 1B: 40 mm,
thickness of the element 127 in FIG. 1B: 3 mm,
length of the element 117 in FIG. 1B: 780 mm,
thickness of the element 117 in FIG. 1B: 3 mm,
length of the elements 106 and 108 in FIG. 4 (i.e. length of the chamber 80): 1100 mm,
diameter of the element 152: 720 mm,
diameter of the hole 124: 740 mm.

With reference to FIGS. 3 to 8, it should be specified that the first elevation (i.e. that of FIG. 3) corresponds to a plane slightly higher than the upper surface of the wall 137, that the second elevation (i.e. that of FIG. 4) corresponds to an intermediate plane between the wall 137 and the wall 127, that the third elevation (i.e. that of FIG. 5) corresponds to a plane passing through the wall 127, that the fourth elevation (i.e. that of FIG. 6) corresponds to a plane slightly lower than the lower surface of wall 127, that the fifth elevation (i.e. that of FIG. 7) corresponds to a slightly higher plane than the upper surface of wall 117, that the sixth elevation (i.e. that of FIG. 8) corresponds to a plane passing through the wall 117. It should be noted that in these figures the section hatchings have been omitted for visual clarity.

FIG. 9 and FIG. 10 refer to a second embodiment 200 of a reaction chamber according to the present invention.

This second embodiment differs from the first one only in the chamber; in fact, the chamber 280 is somewhat different from the chamber 80.

The chamber 280 includes a box-shaped element 281 made of quartz that corresponds exactly to that of the chamber 80.

The box-shaped element 281 is provided with a cavity, also box-shaped, within which a covering system is housed, which may be identical (or similar) to the system 90 of the first embodiment; in FIG. 9, the components 110, 120 and 130 of the covering system are shown with the same references as those of the system 90. The chamber 280 has two flanges 282 and 283 at the longitudinal ends of the element 281. The two flanges respectively have openings for the reaction gases entering the chamber cavity and for the exhaust gases exiting the chamber cavity.

In this second embodiment, the elements of the covering system extend until they at least partially enter the flange openings, but do not protrude from these openings. The chamber 280 has two partition walls 286 and 287 on the upper outer surface, the function of which will be explained hereinafter; these extend transversally to the longitudinal direction of the chamber 280 and are curved in shape; this shape substantially reflects the shape of a susceptor disc in the inner space defined by the covering system.

The chamber 280 has a transparent window (e.g. 10-20 mm wide) in its upper wall that is adapted to measure the temperature of a susceptor or substrates.

In FIG. 10, the chamber 280 is shown associated with a tank 300 provided with a cavity 301 adapted to be filled with water (preferably demineralised) during operation of the reactor or an equivalent liquid.

The chamber 280 is mounted on the tank 300 in such a way that the inner surface of the chamber faces the cavity 301 of the tank 300; in particular, the flanges 282 and 283 are outside the tank 300 and substantially adjacent to the vertical walls of the tank 300.

As schematically shown in FIG. 10, in use, the level of water in the cavity 301 is such that it slightly touches the lower surface of the chamber 280 and exceeds it by a small amount, e.g. 1-10 mm, so as to cool it. Typically, such water is circulated and cooled.

On the lower surface of the chamber 280, cooling is obtained partly by gaseous flow (typically air flow) and partly by liquid flow (typically flow of preferably demineralised water).

The liquid flow develops between the two partition walls 286 and 287 and ends up in the cavity 301 of the tank 300 cascading down from the edges of the upper wall of the chamber 280; this is indicated schematically by the arrows in FIG. 10. The gaseous flow develops elsewhere.

Although not shown in FIG. 10, an inductor (suitably electrically insulated) is located within the cavity 301 to heat by electromagnetic induction at least one susceptor disc located in the inner space defined by the covering system; reference may be made, for example, to Patent Document WO2018083582.

It is understood from the foregoing that a reaction chamber according to the present invention may be applied in epitaxial reactors in particular for the growth of silicon on silicon substrates.

One or more of the technical characteristics of the present invention may be advantageously combined with one or more of the technical features of previous inventions of the same Applicant, for example, those described and shown in International Patent Applications WO2016001863, WO2017137872, WO2017163168, WO2018065852 and WO2018083582, which are incorporated herein by reference.

According to a further aspect, the present invention relates precisely to the inner covering elements of the reaction chamber, i.e. the components that make up the covering system, for example, with reference to the covering system 90 shown in FIG. 1, the covering elements are referred to as 110, 120, 130. Advantageously, each of these elements may be made entirely of quartz. Advantageously, each of these elements may have its own configuration (in FIG. 1 they have three different configurations and three different sizes) specifically adapted to form the covering system when these components are assembled and fitted.

1. Reaction chamber for an epitaxial reactor, the chamber being provided with a cavity wherein reaction and deposition processes of semiconductor material on substrates occur, and comprising a covering system located within said cavity,
wherein said cavity is surrounded by four walls,
wherein said covering system comprises:
a lower covering element resting on a lower wall of said cavity, and
an upper covering element resting on said lower covering element;
wherein said lower covering element and said upper covering element define an inner space included in said cavity and an outer space included in said cavity, and create four walls surrounding said inner space,
wherein the walls of said inner space are spaced from the walls of said cavity through an empty space,
wherein said inner space is adapted to accommodate at least one substrate subject to deposition of semiconductor material,
wherein said inner space is isolated from said outer space.

2. Reaction chamber according to claim 1,
wherein the walls of the chamber are made entirely of quartz, and
wherein the covering system is made entirely of quartz.

3. Reaction chamber according to claim 2,
wherein said covering system is configured so as to house at least one rotating disc of a substrate support susceptor, said disc being made of graphite and adapted to be heated by induction.

4. Reaction chamber according to claim 1,
wherein said covering system further comprises a base covering element, which rests directly on a lower wall of said cavity, and
wherein said lower covering element rests on said base covering element.

5. Reaction chamber according to claim 4, wherein said base covering element rests directly on said lower wall of said cavity only through feet.

6. Reaction chamber according to claim 4, wherein said base covering element is in the form of a flat rectangular slab.

7. Reaction chamber according to claim 4, wherein said base covering element is made of transparent quartz.

8. Reaction chamber according to claim 4, wherein said base covering element consists of two pieces which mechanically couple to each other, in particular wherein a first one of the two pieces is located upstream and a second one of the two pieces is located downstream in relation to a reaction gas flow direction.

9. Reaction chamber according to claim 4, wherein said base covering element has a central hole adapted for the passage of a rotation shaft of a substrate supporting susceptor.

10. Reaction chamber according to claim 1, wherein said upper covering element is in the form of a flat rectangular slab preferably with two shoulders at two opposite edges of the flat slab.

11. Reaction chamber according to claim 10, wherein said upper covering element is made of transparent quartz.

12. Reaction chamber according to claim 10, wherein said upper covering element consists of a single piece.

13. Reaction chamber according to claim 1, wherein said lower covering element is in the form of a flat rectangular slab preferably with shoulders in correspondence of at least some edges of the flat slab.

14. Reaction chamber according to claim 13, wherein said lower covering element is made of opaque quartz.

15. Reaction chamber according to claim 13, wherein said lower covering element consists of two pieces which mechanically couple to each other, in particular wherein a first one of the two pieces is located upstream and a second one of the two pieces is located downstream considering a reaction gas flow direction.

16. Reaction chamber according to claim 13, wherein said lower covering element has a central hole adapted to receive a disc of a substrate supporting susceptor.

17. Reaction chamber according to claim 15, wherein said lower covering element has shoulders at two opposite edges of the flat slab and/or shoulders at said central hole.

18. Inner covering element for a reaction chamber of an epitaxial reactor, said element being configured so as to be a component of the covering system (90) of the reaction chamber according to any claim 1.

19. Inner covering element according to claim 18, said element being entirely made of quartz.

20. Epitaxial reactor comprising at least one reaction chamber according to claim 1.
